(19) United States
(12) Patent Application Publication
(10) Pub. No.: US 2004/0201089 A1
(43) Pub. Date: Oct. 14, 2004

(54) Semiconductor devices and manufacturing methods therefore

(75) Inventor: Koji Yamaguchi, Suwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/795,253

(22) Filed: Mar. 9, 2004

(30) Foreign Application Priority Data
Mar. 20, 2003 (JP) 2003-078093

(51) Int. Cl. H01L 21/50; H01L 23/48

(52) U.S. Cl. 257/686; 438/109; 257/777; 257/778; 438/108

(57) ABSTRACT

To provide methods to manufacture semiconductor devices that are excellent in production efficiency. A method to manufacture a semiconductor device includes mounting a first semiconductor chip having first electrodes and second electrodes on a wiring substrate having a wiring pattern, such that a surface on the opposite side of a surface thereof having the first and second electrodes and faces the wiring substrate, and then, mounting a second semiconductor chip having third electrodes on the first semiconductor chip in a region where the first electrodes are formed, and electrically connecting the first electrodes and the third electrodes that are opposed to one another.

### BACKGROUND OF THE INVENTION

1. Field of Invention

The present invention relates to semiconductor devices and manufacturing methods therefore.

2. Description of Related Art

Stacked layered type semiconductor devices having a plurality of semiconductor chips stacked in layers have been known in the related art. If items handled during the process of manufacturing such semiconductor devices are in configurations that are easy to handle, the efficiency in manufacturing such stacked layered type semiconductor devices can be enhanced. Also, if the items are in configurations that are easy to handle, stacked layered type semiconductor devices can be manufactured by using a facility that has already been in use, so that there is no need to build a new facility, Thus, the manufacturing cost can be substantially reduced.

### SUMMARY OF THE INVENTION

The present invention provides a method to manufacture semiconductor devices and semiconductor devices, which are excellent in production efficiency.

A method to manufacture a semiconductor device in accordance with an aspect of the present invention includes: mounting a first semiconductor chip having first electrodes and second electrodes on a wiring substrate having a wiring pattern, such that a surface opposite to a surface having the first and second electrodes faces the wiring substrate; and then mounting a second semiconductor chip having third electrodes on the first semiconductor chip in a region where the first electrodes are formed, and electrically connecting the first electrodes and the third electrodes that are opposed to each other.

According to an aspect of the present invention, since the first semiconductor chip is initially mounted on the wiring substrate, the later mounting of the second semiconductor chip can be conducted in a state of the wiring substrate. Accordingly, its handling in the manufacturing process is made easier and a semiconductor device can be effectively manufactured.

A method to manufacture a semiconductor device may further include electrically connecting the second electrodes and the wiring pattern with wires.

In the method to manufacture a semiconductor device, the wiring substrate may include a concave section and at least a part of the first semiconductor chip may be disposed inside the concave section.

Consequently, a semiconductor device that is thin and excellent in mountability can be manufactured.

In the method to manufacture a semiconductor device, the surface on the opposite side of the surface of the first semiconductor chip having the first and second electrodes may be opposed to a bottom surface of the concave section.

A method to manufacture a semiconductor device in accordance with an aspect of the present invention includes: mounting a first semiconductor chip having first electrodes and second electrodes on a wiring substrate having a wiring pattern and an opening formed therein, such that a region of the first semiconductor chip where the first electrodes are formed is exposed through the opening and electrically connecting the wiring pattern and the second electrodes that are opposed to each other; and then mounting a second semiconductor chip having third electrodes on the first semiconductor chip in a region where the first electrodes are formed, and electrically connecting the first electrodes and the third electrodes that are opposed to each other.

According to an aspect of the present invention, since the first semiconductor chip is initially mounted on the wiring substrate, the later mounting of the second semiconductor chip can be conducted in a state of the wiring substrate. Accordingly, its handling in the manufacturing process is made easier, and a semiconductor device can be effectively manufactured.

The method to manufacture a semiconductor device, the opening may be formed in a bottom surface of the concave section of the wiring substrate and at least a part of the first semiconductor chip may be disposed inside the concave section.

Consequently, a semiconductor device that is thin and excellent in mountability can be manufactured.

The method to manufacture a semiconductor device may further include, after the mounting of the first and second semiconductor chips on the wiring substrate, forming external terminals on the wiring substrate.

In the method to manufacture a semiconductor device, the first semiconductor chip may have an outer configuration larger than an outer configuration of the second semiconductor chip.

A semiconductor device in accordance with an aspect of the present invention may be manufactured by the methods to manufacture a semiconductor device recited above.

### BRIEF DESCRIPTION OF THE DRAWINGS

FIG. 1 is a schematic showing a method to manufacture a semiconductor device in accordance with a first exemplary embodiment of the present invention;

FIG. 2 is a schematic showing the method to manufacture a semiconductor device in accordance with the first exemplary embodiment of the present invention;

FIG. 3 is a schematic showing the method to manufacture a semiconductor device in accordance with the first exemplary embodiment of the present invention;

FIG. 4 is a schematic showing the method to manufacture a semiconductor device in accordance with the first exemplary embodiment of the present invention;

FIG. 5 is a schematic showing the method to manufacture a semiconductor device in accordance with the first exemplary embodiment of the present invention;

FIG. 6 is a schematic showing a circuit substrate having a semiconductor device in accordance with an exemplary embodiment of the present invention mounted thereon;

FIG. 7 is a schematic showing an electronic device having a semiconductor device in accordance with an exemplary embodiment of the present invention;

FIG. 8 is a schematic showing an electronic device having a semiconductor device in accordance with an exemplary embodiment of the present invention;

FIG. 9 is a schematic showing a method to manufacture a semiconductor device in accordance with a second exemplary embodiment of the present invention;

FIG. 10 is a schematic showing the method to manufacture a semiconductor device in accordance with the second exemplary embodiment of the present invention;

FIG. 11 is a schematic showing the method to manufacture a semiconductor device in accordance with the second exemplary embodiment of the present invention;

FIG. 12 is a schematic showing the method to manufacture a semiconductor device in accordance with the second exemplary embodiment of the present invention; and

FIG. 13 is a schematic showing the method to manufacture a semiconductor device in accordance with the second exemplary embodiment of the present invention.

### DETAILED DESCRIPTION OF EXEMPLARY EMBODIMENTS

Exemplary embodiments of the present invention are described below with reference to the accompanying drawings. However, the present invention is not limited to the exemplary embodiments described below.

First Exemplary Embodiment

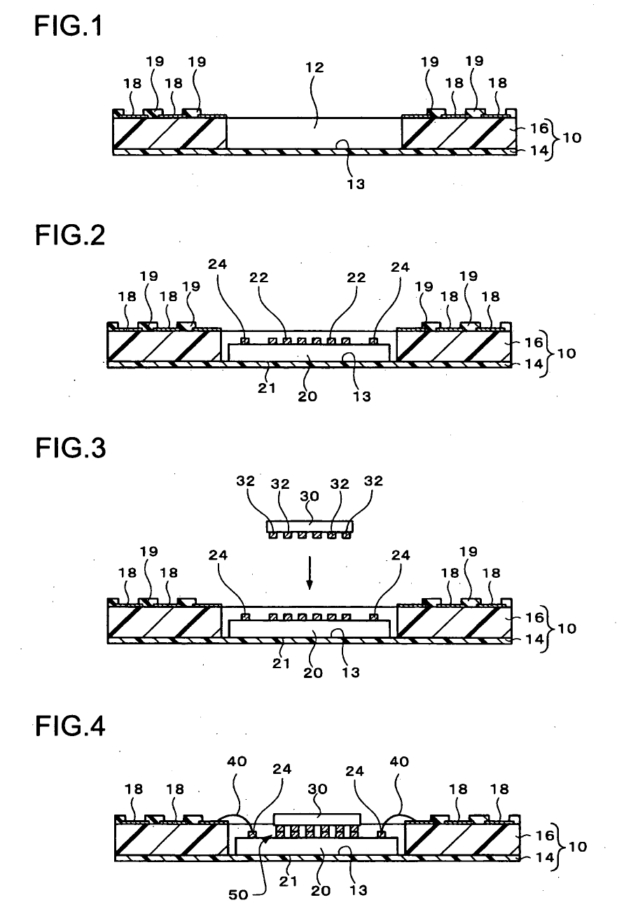

FIG. 1-FIG. 5 are views to describe a method to manufacture a semiconductor device in accordance with a first exemplary embodiment of the present invention.

First, a wiring substrate 10 is prepared (see FIG. 1). The material of the wiring substrate 10 is not particularly limited, and may be formed with either organic material or inorganic material, or may be composed of a compound structure using these materials. As an organic substrate, for example, a substrate composed of polyethylene terephthalate (PET) may be used. Also, as a substrate that is formed with inorganic material, for example, a ceramics substrate or a glass substrate can be used. As a compound structure using organic and inorganic materials, for example, a glass epoxy substrate may be recommended. Also, as the wiring substrate 10, a flexible substrate may be used, or a rigid substrate may be used.

As indicated in FIG. 1, the wiring substrate 10 may have a concave section 12. On a first substrate 14, a second substrate 16 having an opening may be mounted, to thereby form the wiring substrate 10 having the concave section 12. In other words, the wiring substrate 10 may be formed from the first and second substrates 14 and 16.

The wiring substrate 10 includes a wiring pattern 18. The wiring pattern 18 can be formed through, for example, adhering a metal foil, such as a copper foil to the wiring substrate 10 through adhesive, conducting photolithography and then conducting etching. Alternatively, sputtering may be conducted to form the wiring pattern 18. Alternatively, the wiring pattern 12 may be formed by using an additive method in which the wiring pattern 18 is formed by electroless plating. Also, the wiring substrate 10 may have a resist 19. The resist 19 can reduce or prevent short circuit of the wiring pattern 18, and thus a highly reliable semiconductor device can be manufacture.

Next, a first semiconductor chip 20 is mounted on the wiring substrate 10 (see FIG. 2). An integrated circuit may be formed in the first semiconductor chip 20. The plane configuration of the first semiconductor chip 20 may generally be a rectangular, but is not particularly limited. The first semiconductor chip 20 includes first electrodes 22 and second electrodes 24. The first and second electrodes 22 and 24 may be electrically connected to the integrated circuit. The first and second electrodes may be formed from thin and flat pads that may be composed of aluminum, and bumps formed on the pads. However, pads without bumps formed thereon may be used as the electrodes. For example, as the first electrodes 22, electrodes having pads and bumps may be used. Also, as the second electrodes 24, either electrodes formed from pads without bumps or electrodes having pads and bumps may be used. Disposition of the first and second electrodes 22 and 24 is not particularly limited. However, for example, the first electrodes 22 may be disposed near the central section of the first semiconductor chip 20, and the second electrodes 24 may be disposed in a manner to surround the area where the first electrodes 22 are disposed, and adjacent to the circumferential section of the first semiconductor chip 20. A passivation film (not shown) may be formed on the first semiconductor chip 20 while avoiding at least a part of the pads. The passivation film may be formed from, for example, SiO2, SiN or polyimide resin.

In a method to manufacture a semiconductor device in accordance with the present exemplary embodiment, the first semiconductor chip 20 is mounted in a manner that its surface 21 on the opposite side of the surface having the first and second electrodes 22 and 24 faces the wiring substrate 10. The first semiconductor chip 20 may be fixed to the wiring substrate 10 by, for example, adhesive not shown. When the wiring substrate 10 includes the concave section 12, at least a part of the first semiconductor chip 20 may be disposed inside the concave section 12. Consequently, a semiconductor device that is thin and excels in mountability can be manufactured. In this case, the surface 21 of the first semiconductor chip 20 may be placed opposed to a bottom surface 13 of the concave section 12 (see FIG. 2).

Next, a second semiconductor chip 30 having third electrodes 32 is mounted on the first semiconductor chip 20 in a region wherein the first electrodes 22 are formed, the first electrodes 22 and the third electrodes 32 are opposed and electrically connected to one another (see FIG. 3). The third electrodes 32 of the second semiconductor chip 30 may be formed from pads and bumps, for example. Also, the third electrodes 32 may be formed on one surface of the second semiconductor chip 30, in plural rows and plural columns. For example, the first electrodes 22 and the third electrodes 32 may be brought in contact with one another, and the first and third electrodes 22 and 32 may be electrically connected by metal bonding under application of heat and pressure. Alternatively, by using an ACF (anisotropic conductive film) or ACP (anisotropic conductive paste), conductive particles may be provided between the first electrodes 22 and the third electrodes 32 to thereby electrically connect the first and third electrodes 22 and 32. The first and third electrodes 22 and 32, as bonded form an electrical connection section 50 that electrically connects the first and second semiconductor chips 20 and 30. The second semiconductor chip 30 may be mounted on the first semiconductor chip 20 through adhesive. By hardening the adhesive, a protection member (not shown) that protects the electrical connection section 50 may be formed. It is noted that the outer configuration of the first semiconductor chip 20 may be larger than the outer configuration of the second semiconductor chip 30.

As described above, in the method to manufacture a semiconductor device in accordance with the present exemplary embodiment, after the first semiconductor chip 20 is mounted on the wiring substrate 10, the mounting of the second semiconductor chip 30 on the first semiconductor chip 20 is conducted. Consequently, the first and second semiconductor chips 20 and 30 do not need to be handled in a state in which they are stacked in layers. The mounting of the second semiconductor chip 30 can be conducted on the wiring substrate, such that its handling in the manufacturing process is facilitated, and thus the efficiency in manufacturing semiconductor devices can be enhanced.

The method to manufacture a semiconductor device in accordance with the present exemplary embodiment may further include electrically connecting the second electrodes 24 of the first semiconductor chip 20 and the wiring pattern 18 with wires 40 (see FIG. 4). The wires 40 may be formed by any one of the bonding tools that are known. Also, any suitable wires can be used as the wires 40. Also, the step of forming the wires 40 may be conducted either before or after the step of mounting the second semiconductor chip 30.

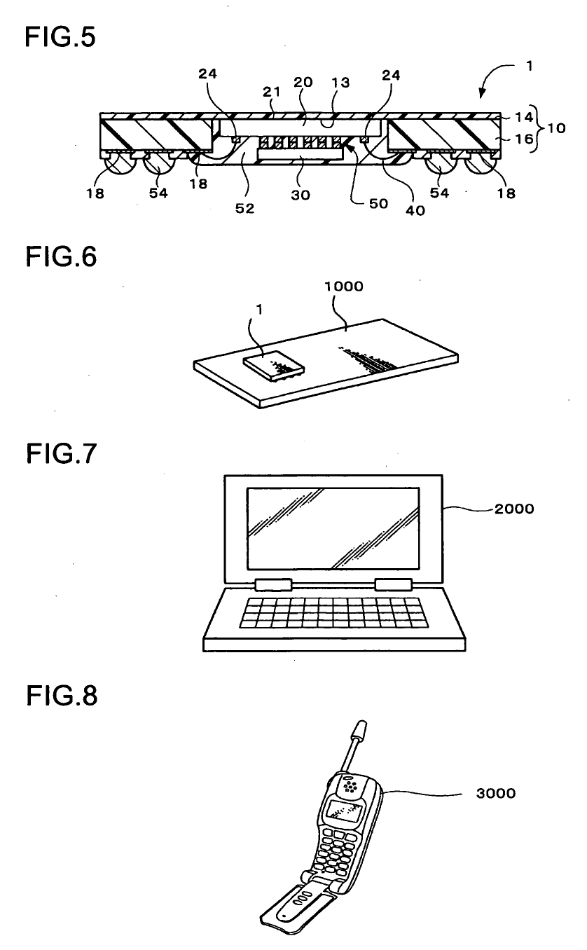

Finally, through conducting the steps of forming a resin layer 52 and external terminals 54, a semiconductor device 1 can be manufactured (see FIG. 5).

The semiconductor device 1 that is manufactured by the method to manufacture a semiconductor device in accordance with the present exemplary embodiment includes a wiring substrate 10 having a wiring pattern 18. The semiconductor device 1 includes a first semiconductor chip 20 that is mounted on the wiring substrate 10. The semiconductor device 1 includes a second semiconductor chip 30 that is mounted on the first semiconductor chip 20. The semiconductor device 1 includes an electrical connection section 50 that is formed between the first semiconductor chip 20 and the second semiconductor chip 30 to electrically connect the first and second semiconductor chips 20 and 30. Second electrodes 24 are formed on a surface of the first semiconductor chip 20 on which the second semiconductor chip 30 is mounted, and in a portion thereof that is exposed out of the second semiconductor chip 30. A surface 21 of the first semiconductor chip 20 on the opposite side of the surface where the first and second electrodes 22 and 24 are formed is opposed to the wiring substrate 10. The first semiconductor chip 1 may have wires 40 that electrically connect the wiring pattern 18 and the second electrodes 24. FIG. 6 shows a circuit substrate 1000 on which the semiconductor device 1 described above is mounted. Also, as electronic devices each having the semiconductor device 1, a notebook type personal computer 2000 is shown in FIG. 7, and a portable telephone 3000 is shown in FIG. 8.

Second Exemplary Embodiment

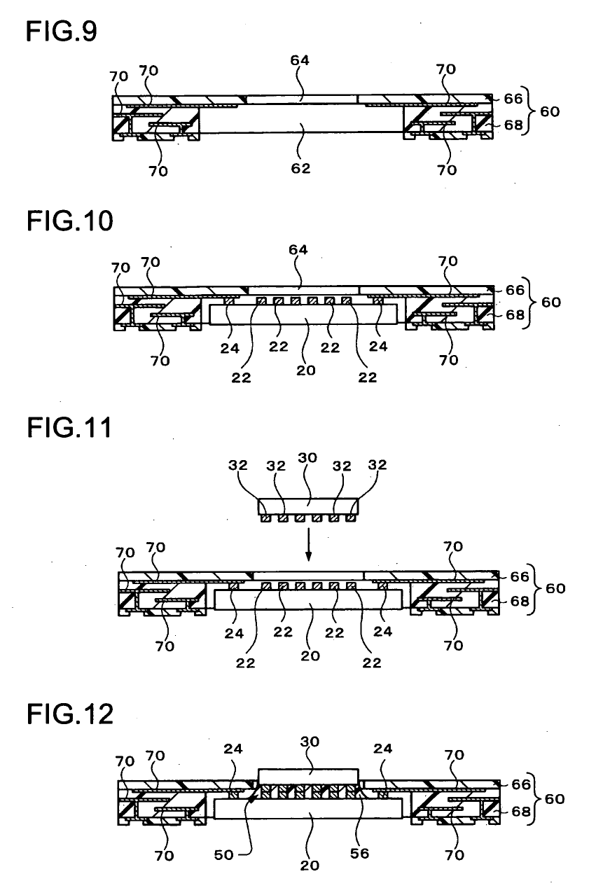

FIG. 9-FIG. 13 are views to describe a method to manufacture a semiconductor device in accordance with a second exemplary embodiment of the present invention. The contents described above can also be applied to the present exemplary embodiment as long as they are applicable.

In the present exemplary embodiment, first, a wiring substrate 60 having an opening is prepared (see FIG. 9) The material of the wiring substrate 60 is not particularly limited, and the contents of the wiring substrate 10 described above may likewise be applicable. Further, although the configuration of the wiring substrate is neither particularly limited, the wiring substrate 60 may be in a configuration having a concave section 62 and an opening 64 formed in a bottom surface of the concave section 62. The substrate 60 having the concave section 62 and the opening 64 may be formed through mounting a second substrate 68 having an opening on a first substrate 66 having an opening 64. The second substrate 68 may have a wiring pattern 70 formed in multiple layers, as indicated in FIG. 9. The wiring pattern 70 may be formed by any one of the known methods.

Next, as shown in FIG. 10, the first semiconductor chip 20 described above is prepared, and mounted on the wiring substrate 60 such that an area of the first semiconductor chip 20 in which the first electrodes 22 are formed is exposed through the opening 64, and the wiring pattern 70 and the second electrodes 24 that are opposed to each other are electrically connected to each other. In other words, an alignment is conducted such that the area where the first electrodes 22 are formed overlaps the opening 64, and then the wiring pattern 70 and the second electrodes 24 that are opposed to each other are electrically connected. For example, the second electrodes 24 are brought in contact with the wiring pattern 70, and the second electrodes 24 and the wiring pattern 70 may be electrically connected by metal bonding through application of heat and pressure. Alternatively, by using an ACF (anisotropic conductive film) or ACP (anisotropic conductive paste), the second electrodes 24 and the wiring pattern 70 may be electrically connected to each other.

When the wiring substrate 60 includes the concave section 62, at least a part of the first semiconductor chip 20 may be disposed inside the concave section 62. Consequently, a semiconductor device that is thin and excellent in mountability can be manufactured.

Next, as indicated in FIG. 11, a second semiconductor chip 30 having third electrodes 32 is mounted on the first semiconductor chip 20 in the region where the first electrodes 22 are formed. The first electrodes 22 and the third electrodes 32 that are opposed to each other are electrically connected. The first and second electrodes 22 and 32 are bonded to form an electrical connection section 50, and the first semiconductor chip 20 and the second semiconductor chip 30 are electrically connected to each other by the electrical connection section 50. In the method to manufacture a semiconductor device in accordance with the present exemplary embodiment also, the first and second semiconductor chips 20 and 30 do not need to be handled in a state in which they are stacked in layers, and the step of mounting the second semiconductor chip 30 can be conducted on the wiring substrate, such that its handling in the manufacturing process is facilitated, and thus the efficiency in manufacturing semiconductor devices can be enhanced. It is noted that, in the present exemplary embodiment, the wiring substrate 60 includes the opening 64, and the first semiconductor chip 20 is mounted thereon in a manner that the first electrodes 22 are exposed through the opening 64 thus formed. Accordingly, even after the first semiconductor chip 20 is mounted on the wiring substrate 60, the first electrodes 22 and the third electrodes 32 are opposed to each other and electrically connected to each other.

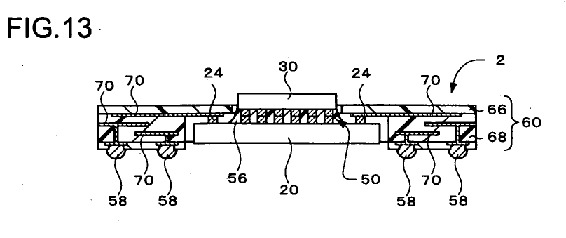

Next, a resin layer 56 may be formed. The resin layer 56 may be formed to cover the electrical connection section 50, as shown in FIG. 12, or may be formed to cover not only the electrical connection section 50 but also the electrodes 24, but its range is not particularly limited. Consequently, a semiconductor device that is highly reliable against stresses can be manufactured. Then, through the forming external terminals 58, a semiconductor device 2 can be manufactured (see FIG. 13).

The semiconductor device 2 that is manufactured by the method to manufacture a semiconductor device in accordance with the present exemplary embodiment includes a wiring substrate 60. The wiring substrate 60 has a wiring pattern 70 formed thereon. The wiring substrate 60 includes an opening 64 formed therein. The semiconductor device 2 includes a first semiconductor chip 20. The semiconductor device 2 includes a second semiconductor chip 30 that is mounted on the first semiconductor chip 20. At least a part of the second semiconductor chip 30 may be disposed inside the opening 64. The semiconductor device 2 includes an electrical connection section 50 that is formed between the first and second semiconductor chips 20 and 30, and that electrically connects the first and second semiconductor chips 20 and 30. Second electrodes 24 are formed on a surface of the first semiconductor chip 20 on which the second semiconductor chip 30 is mounted in an area thereof that is exposed outside the second semiconductor chip 30, and the second electrodes 24 are opposed to and electrically connected to the wiring pattern 70. It is noted that the semiconductor device 2 may have external terminals 58.

The present invention is not limited to the exemplary embodiments described above, and many modification can be made. For example, the present invention may include compositions that are substantially the same as the compositions described in the exemplary embodiments (for example, a composition that has the same functions, the same methods and the results, or a composition that has the same objects and results). Also, the present invention includes compositions in which portions not essential in the compositions described in the exemplary embodiments are replaced with others. Also, the present invention includes compositions that achieve the same functions and effects or achieve the same objects as those of the compositions described in the exemplary embodiments. Furthermore, the present invention includes compositions that include known technology added to the compositions described in the exemplary embodiments.

What is claimed is:

1. A method to manufacture a semiconductor device, comprising:
mounting a first semiconductor chip, having first electrodes and second electrodes, on a wiring substrate having a wiring pattern, such that a first surface, opposite to a second surface having the first and second electrodes, faces the wiring substrate; and then
mounting a second semiconductor chip, having third electrodes, on the first semiconductor chip in a region where the first electrodes are formed, and electrically connecting the first electrodes and the third electrodes that are opposed to each other.

2. The method to manufacture a semiconductor device according to claim 1, further comprising:
electrically connecting the second electrodes and the wiring pattern with wires.

3. The method to manufacture a semiconductor device according to claim 1, the wiring substrate including a concave section and at least a part of the first semiconductor chip being disposed inside the concave section.

4. The method to manufacture a semiconductor device according to claim 3, the first surface opposed to a bottom surface of the concave section.

5. A method to manufacture a semiconductor device, comprising:
mounting a first semiconductor chip, having first electrodes and second electrodes, on a wiring substrate having a wiring pattern and an opening formed therein, such that a region of the first semiconductor chip, where the first electrodes are formed, is exposed through the opening and electrically connecting the wiring pattern and the second electrodes that are opposed to each other; and then
mounting a second semiconductor chip, having third electrodes, on the first semiconductor chip in a region where the first electrodes are formed, and electrically connecting the first electrodes and the third electrodes that are opposed to each other.

6. The method to manufacture a semiconductor device according to claim 5, the wiring substrate including a concave section and the opening being formed in a bottom surface of the concave section of the wiring substrate and at least a part of the first semiconductor chip being disposed inside the concave section.

7. The method to manufacture a semiconductor device according to claim 1, further comprising:
after the mounting of the first and second semiconductor chips on the wiring substrate, forming external terminals on the wiring substrate.

8. The method to manufacture a semiconductor device according to claim 1, the first semiconductor chip having an outer configuration larger than an outer configuration of the second semiconductor chip.

9. A semiconductor device manufactured by the method of manufacturing a semiconductor device recited in claim 1.
